(19) United States
(12) Patent Application Publication
(10) Pub. No.: US 2017/0371110 A1
(43) Pub. Date: Dec. 28, 2017

(54) Optical Transceiver With a Mirrored Submount and a Laser Diode for Laser-to-Fiber Coupling

(71) Applicant: Futurewei Technologies, Inc., Plano, TX (US)

(72) Inventors: Ning Cheng, Basking Ridge, NJ (US); Wenbiao Zhong, Shenzhen (CN)

(21) Appl. No.: 15/623,176

(22) Filed: Jun. 14, 2017

Related U.S. Application Data
(60) Provisional application No. 62/353,777, filed on Jun. 23, 2016.

(51) Int. Cl. G02B 6/42; H01S 5/022; H01S 5/00; H04B 10/50

(52) U.S. Cl. CPC G02B 6/4206; H04B 10/503; H01S 5/02248; G02B 6/4214; H01S 5/0071; G02B 6/4246; H01S 5/0224

(57) ABSTRACT

An optical device comprises a laser diode configured to emit an optical signal, wherein the optical signal diffracts into a plurality of emitted optical signals, and a submount comprising a mirror, wherein the mirror is configured to at least partially reflect and redirect the plurality of emitted optical signals to produce a plurality of reflected optical signals, and wherein the mirror is further configured to substantially reshape a vertical far field angle of the optical signal.

### CROSS REFERENCE TO RELATED APPLICATIONS

The present application claims benefit of U.S. Provisional Patent Application No. 62/353,777 filed Jun. 23, 2016 by Ning Cheng, et. al. and entitled “Optical Transceiver With a Mirrored Submount and a Distributed Feedback (DFB) Laser for Laser-to-Fiber Coupling,” which is incorporated herein by reference as if reproduced in its entirety.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Passive optical networks (PONs) have been widely deployed by operators to provide broadband services. PONs include fiber-to-the-homes (FTTHs). There are currently more than one hundred million FTTH users worldwide. Each FTTH user requires an optical network unit (ONU) at the customer's premise. Thus, cost reduction is important for large scale PON deployment.

### SUMMARY

In some embodiments, an optical device includes a laser diode configured to emit an optical signal, wherein the optical signal diffracts into a plurality of emitted optical signals, and a submount comprising a mirror, wherein the mirror is configured to at least partially reflect and redirect the plurality of emitted optical signals to produce a plurality of reflected optical signals, and wherein the mirror is further configured to substantially reshape a vertical far field angle of the optical signal.

In some embodiments, the plurality of reflected optical signals are substantially collimated and focused before being received at an optical fiber. In some embodiments, the mirror is a flat mirror, wherein a plane of the flat mirror is substantially parallel with an active layer of the laser diode. In some embodiments, the laser diode is flip-chip bonded to the submount. In some embodiments, the optical device further includes a lens positioned between the laser diode and the optical fiber, wherein the lens is configured to focus the plurality of emitted optical signals and the plurality of reflected optical signals together. In some embodiments, the mirror is a substantially doubly concave mirror with a substantially toroidal shape. In some embodiments, the mirror is a substantially doubly concave mirror with a substantially toroidal shape, wherein the mirror is configured to reflect light by about 90 degrees. In some embodiments, the mirror is configured to focus the plurality of reflected optical signals toward an acceptance region of an optical fiber, and wherein the acceptance point on the optical fiber is located substantially at an image plane of the mirror.

In some embodiments, an optical device includes a laser diode configured to emit an optical signal, wherein the optical signal diffracts into a plurality of emitted optical signals, and a submount comprising a mirror, wherein the mirror is configured to at least partially reflect and redirect the plurality of emitted optical signals to produce a plurality of reflected optical signals, and wherein the mirror is further configured to substantially reshape a vertical far field angle and a horizontal far field angle of the optical signal.

In some embodiments, the plurality of emitted optical signals and the plurality of reflected optical signals are substantially collimated and focused before being received by the optical fiber. In some embodiments, the laser is flip-chip bonded to the submount. In some embodiments, the optical device further includes a lens positioned between the laser diode and the optical fiber, wherein the lens is configured to focus the plurality of emitted optical signals and the plurality of reflected optical signals together. In some embodiments, the mirror is a substantially doubly concave mirror with a substantially toroidal shape, and wherein the mirror is configured to focus the plurality of reflected optical signals toward an acceptance point of an optical fiber. In some embodiments, the mirror is a substantially doubly concave mirror with a substantially toroidal shape, and wherein the mirror is configured to reflect light by about 90 degrees.

In some embodiments, a method includes generating, via a laser diode disposed on a submount, an optical signal, wherein a mirror is disposed on the submount, wherein the optical signal is emitted from the laser diode as a plurality of emitted optical signals, reshaping a far field angle of the optical signal by reflecting, via the mirror, a portion of the plurality of emitted optical signals to produce a plurality of reflected optical signals, and directing the plurality of emitted optical signals and the plurality of reflected optical signals towards a core of an optical fiber.

In some embodiments, reshaping the far field angle comprises reducing a vertical far field angle relative to the laser diode. In some embodiments, the mirror is a flat mirror, wherein a plane of the flat mirror is substantially parallel with an active layer of the laser diode. In some embodiments, the mirror is a substantially doubly concave mirror with a substantially toroidal shape, and wherein an image plane of the mirror is substantially located on the core of the optical fiber. In some embodiments, the mirror is a substantially doubly concave mirror with a substantially toroidal shape and wherein the mirror is configured to reflect light by about 90 degrees. In some embodiments, the method further includes transmitting, via an output aperture of the laser diode, the optical signal to an optical fiber, wherein a portion of the plurality of emitted optical signals are reflected from the mirror to the optical fiber.

These and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a diagram of a PON.

FIG. 2 illustrates a conventional optical coupling scheme employing a lens.

FIG. 3 illustrates a portion of the optical coupling scheme in FIG. 2 where the far field angle of the light emitted from the laser diode.

FIG. 4 is a diagram of a transmitter optical assembly (TOSA) according to an embodiment of the disclosure.

FIG. 5 is a diagram of a portion of the TOSA shown in FIG. 4 according to an embodiment of the disclosure.

FIG. 6 is a diagram of a portion of the TOSA in FIG. 4 according to another embodiment of the disclosure.

FIG. 7 is a graph illustrating the optical field from the output of the laser diode after being reflected by a mirror on the submount according to an embodiment of the disclosure.

FIG. 8 is a diagram of a TOSA according to another embodiment of the disclosure.

FIG. 9 is a diagram of a portion of the TOSA according to an embodiment of the disclosure.

FIG. 10 is a diagram of a mirror in the TOSA of FIG. 8 according to various embodiments of the disclosure.

FIG. 11 is a flowchart of a method for reducing a far field angle of a laser diode according to an embodiment of the disclosure.

FIG. 12 is a diagram of an optical device according to an embodiment of the disclosure.

### DETAILED DESCRIPTION

It should be understood at the outset that, although illustrative implementations of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

An optical transceiver in an optical line terminal (OLT) or an ONU of a PON typically includes a bi-directional optical assembly (BOSA). The BOSA includes a TOSA and a receiver optical assembly (ROSA). The TOSA comprises components for optical transmissions, such as a laser diode configured to generate an optical signal, such as light or a light beam, and a receptacle configured to receive an optical fiber. For example, the laser diode generates and emits light toward the optical fiber. However, the light emitted from the laser diode diffracts radially or elliptically as the light travels from the laser diode to the optical fiber. The far field angle of the optical signal emitted from the laser diode is the angle at which the light diverges or diffracts from an output of the laser diode after the light has emitted from the laser diode. The acceptance angle of the optical fiber is the angle at which the optical signal can be received by the optical fiber. Typically, the far field angle on a distributed feedback (DFB) laser is about 20° to 30°. In contrast, the typical acceptance angle of a single mode optical fiber is about 4° to about 5°. This large difference between the far field angle of the optical signal emitted from a laser diode, and the acceptance angle of the optical signal accepted by an optical fiber, results in a coupling loss of light in a TOSA. Thus, the BOSAs used in ONUs and OLTs in a PON experience a low coupling efficiency between the laser diodes and optical fibers, even though lenses are usually used to facilitate the coupling between the laser diodes and optical fibers.

Disclosed herein are embodiments of a TOSA that reduce the coupling loss between a laser diode and an optical fiber, and thus improve coupling efficiency and alignment tolerance of an optical signal in between the laser diode and the optical fiber. For example, a TOSA includes a submount comprising a mirror. The mirror is positioned on the submount such that an optical signal emitted from the laser diode is at least partially reflected such that a far field angle of the optical signal emitted from the laser diode is reduced. The disclosed embodiments involve depositing a submount underneath the laser diode and interposing a mirror between the laser diode and the submount. In one embodiment, a laser diode is flip-chip bonded onto the submount comprising a flat mirror. The term flip-chip bonding refers to flipping a component of the TOSA upside down so that a contact point that is typically on the top surface of the component is now flipped to become the bottom surface of the component. The contact point of the component abuts, or is substantially adjacent to, a contact point disposed on the submount. In another embodiment, the laser diode is disposed onto a mirrored submount with a concave mirror. In an embodiment, the concave mirror is a toroidal or spherical mirror. The flat mirror and the concave mirror are positioned on a location of a surface of the submount to reshape the far field angle of the laser diode to match the acceptance angle of the optical fiber. As such, the disclosed embodiments improve coupling efficiency and alignment tolerance, and thus reduce cost. Further, as the coupling loss is reduced, the requirements on the laser diode output power and slope efficiency are reduced. Therefore, the disclosed embodiments may improve laser diode yield and reduce laser diode cost.

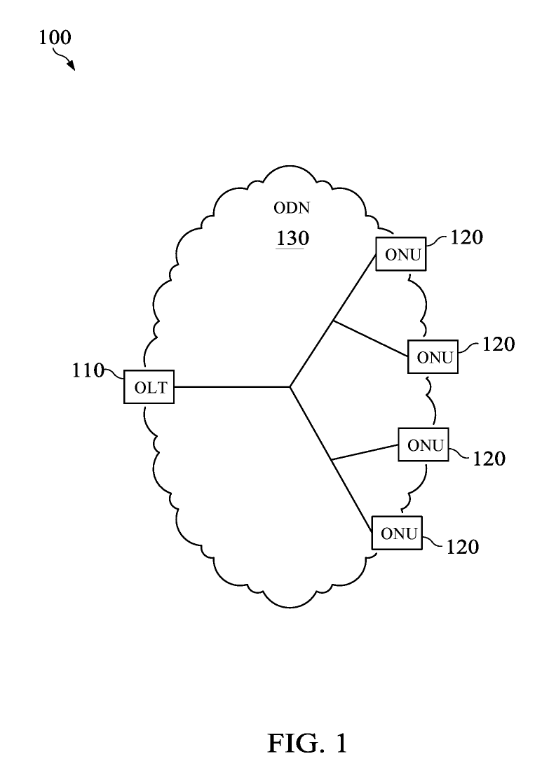

FIG. 1 is a diagram of a PON 100. The PON 100 comprises an OLT 110, a plurality of ONUs 120, and an optical distribution network (ODN) 130 that couples the OLT 110 to the ONUs 120. The PON 100 is suitable for implementing the disclosed embodiments. The PON 100 is a communications network that may not require active components to distribute data between the OLT 110 and the ONUs 120. Instead, the PON 100 may use passive optical components in the ODN 130 to distribute data between the OLT 110 and the ONUs 120.

The OLT 110 communicates with the ONUs 120 and another network. Specifically, the OLT 110 is an intermediary between the other network and the ONUs 120. For instance, the OLT 110 forwards data received from the other network to the ONUs 120 and forwards data received from the ONUs 120 to the other network. The OLT 110 comprises a transmitter and a receiver. When the other network uses a network protocol that is different from the protocol used in the PON 100, the OLT 110 comprises a converter that converts the network protocol to the PON 100 protocol and vice versa. The OLT 110 is typically located at a central location such as a central office (CO), but it may also be located at other suitable locations.

The ODN 130 is a data distribution system that comprises optical fiber cables, couplers, splitters, distributors, and other suitable components. The components may include passive optical components that do not require power to distribute signals between the OLT 110 and the ONUs 120. The components may also include active components such as optical amplifiers that do require power. The ODN 130 extends from the OLT 110 to the ONUs 120 in a branching configuration as shown, but the ODN 130 may be configured in any other suitable point-to-multipoint (P2MP) configuration.

The ONUs 120 communicate with the OLT 110 and a customer, and act as an intermediary between the OLT 110 and the customer. For instance, the ONUs 120 forward data from the OLT 110 to the customer and forward data from the customer to the OLT 110. The ONUs 120 comprise an optical transmitter that converts electrical signals into optical signals and transmits the optical signals to the OLT 110, and an optical receiver that receives optical signals from the OLT 110 and converts the optical signals into electrical signals. The ONUs 120 further comprise a second transmitter that transmits the electrical signals to the customer and a second receiver that receives electrical signals from the customer. ONUs 120 and optical network terminals (ONTs) are similar, and the terms may be used interchangeably. The ONUs 120 are typically located at distributed locations such as customer premises, but they may also be located at other suitable locations.

In an embodiment, each of the ONUs 120 and/or the OLT 110 comprises a TOSA and a ROSA. In various embodiments, the TOSA and the ROSA may be both housed within one transistor outline (TO)-can or the TOSA and the ROSA may be housed within separate TO-cans. The TOSA and the ROSA share components of the BOSA, such as a TO-cap surrounding the TOSA and BOSA, a lens positioned on or formed as part of the TO-cap, and a TO-header upon which the components of the TOSA and ROSA are positioned. The TOSA comprises components for optical transmission, and the ROSA comprises components for optical reception. For example, the TOSA comprises a laser diode, and the ROSA comprises a photodiode. The TOSA may also comprise a receptacle configured to receive and secure an optical fiber. In a TOSA, there may be a gap, or a distance, between the laser diode and the optical fiber. The lens is disposed between the laser diode and the optical fiber.

When an optical signal is emitted from the laser diode, the optical signal typically diverges, or diffracts, in the gap between the laser diode and the optical fiber. While the lens focuses and directs the optical signal emitted from the laser to the optical fiber during operation, the lens does not reduce the far field angle of the laser diode enough to match the acceptance angle of the optical fiber to reduce coupling loss. Typical schemes of reducing coupling loss to increase coupling efficiency and alignment tolerance involve making changes to the structure of the laser diode and/or the optical fiber. However, these changes to the structure of the laser diode and/or the optical fiber are often times intricate and too costly to implement across the millions of ONUs and OLTs in PONs.

Disclosed herein are embodiments of a TOSA that reduce coupling loss between a laser diode and an optical fiber. The embodiments disclosed herein do not involve making complex changes to the structure of the laser diode or the optical fiber. Instead, the embodiments disclosed herein involve interposing a submount comprising a mirror below the laser diode. In an embodiment, the light that is emitted from the laser diode and impinged onto the mirror is at least partially reflected and redirected. In an embodiment, the reflected light reshapes the far field angle of the laser diode.

In an embodiment, the laser diode is flip-chip bonded to the submount such that an active layer of the laser diode is adjacent to the submount. The output of the laser diode is relatively close to the submount when the laser diode is flip-chip bonded to the submount. In this embodiment, a mirror may be formed on a surface of the submount proximate to the laser diode such that the mirror is extended past the output of the laser diode. In this embodiment, when an optical signal is emitted from the output of the laser diode, the diverged beams of the optical signal in the vertical direction will be partially reflected by the mirror on the submount.

In another embodiment, the laser diode may not need to be flip-chip bonded to the submount. In this embodiment, the submount comprises a plateau that extends from an edge of the laser diode comprising the output. The plateau of the submount comprises the mirror. In this embodiment, the mirror is relatively proximate to the output of the laser diode without having to flip-chip bond the laser diode to the submount.

In another embodiment, the submount comprises a concave surface that is bent or curved by about 90° at a predefined distance from the output of the laser diode and the optical fiber. In an embodiment, a concave mirror is formed on the concave surface of the submount. In an embodiment, the concave mirror is a toroidal mirror or a spherical mirror that is radially or elliptically concave. The optical signals impinge on the concave mirror, and the concave mirror reflects the optical signals at substantially 90° and focuses the optical signals toward a point or an area. In an embodiment, the concave surface supports the concave mirror.

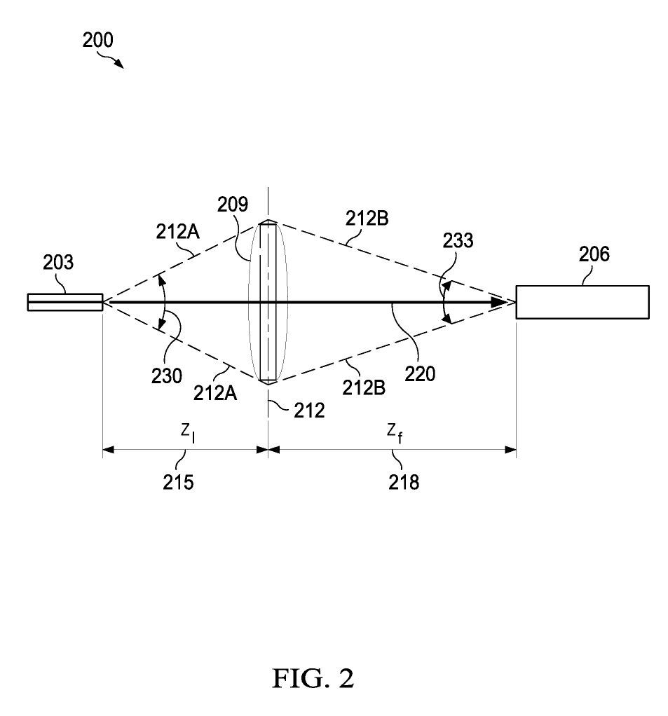

FIG. 2 illustrates a conventional optical coupling scheme 200 employing a lens 209. In the optical coupling scheme 200, the lens 209 is positioned between a laser diode 203 and an optical fiber 206. In an embodiment, the laser diode 203 is a DFB laser diode or any laser diode suitable for emitting light with the desired characteristics. The laser diode 203 may be employed by an ONU such as the ONUs 120 or an OLT such as the OLT 110 to provide an optical source for gigabit PON (GPON) and Ethernet PON (EPON) applications. In an embodiment, the lens 209 is an aspherical lens or any other lens suitable for focusing light emitted from the laser diode 203. In an embodiment, the optical fiber 206 is a standard single-mode fiber (SSMF).

As shown in FIG. 2, the lens 209 is positioned at a point that is a first distance 215 (Z₁) from a laser diode 203 and at a second distance 218 (Z_{f}) from the optical fiber 206. The laser diode 203 emits optical signal 220 that diverges radially outward from the center point of optical signal 220, as shown by the dashed lines 212A. The lens 209 focuses and directs the diverged optical signal, as shown by the dashed lines 212B, to the core of the optical fiber 206. The far field angle 230 of the optical signals emitted from the laser diode 203 is typically about 20° to 30°. The acceptance angle 233 of the optical fiber 206 is typically about 4° to 5°.

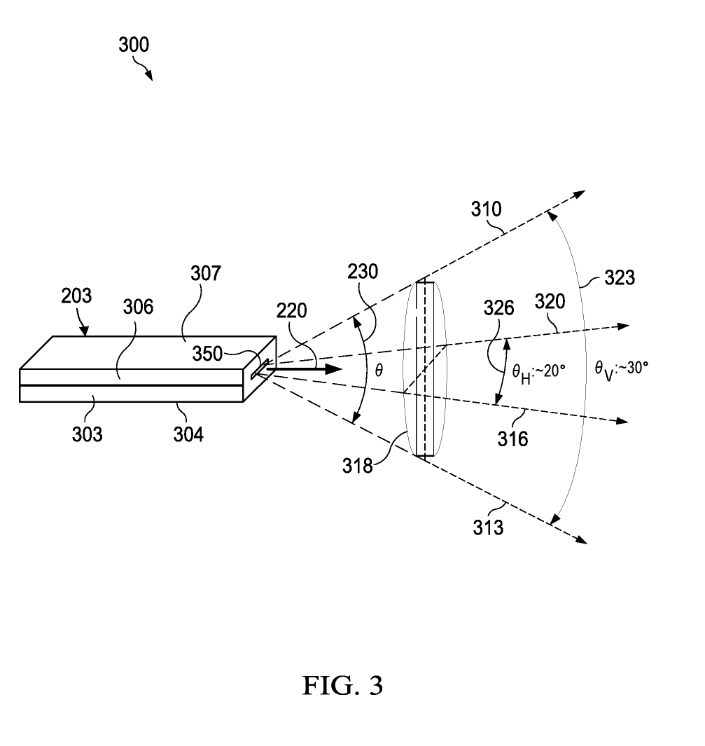

FIG. 3 illustrates a portion 300 of the optical coupling scheme 200, showing the far field angle 230 of the optical signal 220 as the optical signal 220 is emitted from the conventional laser diode 203. As shown in FIG. 3, the laser diode 203 comprises a substrate 303, a lower surface 304 of the laser diode 203 that is substantially opposite an active layer 306, an upper surface 307 of the of the laser diode 203 that is substantially opposite the substrate 303, and an output aperture 350. In a traditional TOSA, a lower surface 304 is positioned on a support block, such as a metal block, of the TOSA. The active layer 306 comprises a waveguide and a grating that is configured to generate the optical signal 220, with the optical signal 220 being emitted by an output aperture 350. Typically, the upper surface 307 radiates more heat than the lower surface 304.

As shown in FIG. 3, optical signal 220 spreads outward as it leaves the output aperture 350, due to diffraction. The optical signal 220 diffracts into several emitted optical signals 310, 313, 316, and 320, creating an elliptical mode field 318. Four dashed lines, showing emission angles, are shown in FIG. 3 for illustrative purposes. In the elliptical mode field 318, light emitted from the laser diode 203 spreads more in the vertical plane than in the horizontal plane. The far field angle 230 comprises a horizontal far field angle (θ_{H}) 326 and a vertical far field angle (θ_{V}) 323. The horizontal far field angle 326 is an angle of divergence of optical signal 220 in a horizontal direction and substantially in the same plane as the active layer 306 of the laser diode 203. The horizontal far field angle 326 of a DFB laser is typically about 20°. The vertical far field angle 323 is an angle of divergence of optical signal 220 in a vertical direction and substantially perpendicular to the active layer 306 of the laser diode 203. The vertical far field angle 323 of a DFB laser is typically about 30°.

However, the mode field of an SSMF that is to accept the emitted light is circular, due to the cross-sectional shape of the fiber. The acceptance angle of the SSMF (i.e., the maximum angle of impinging light as it strikes the end face of the fiber) is about 5°. The angular mismatch between the mode field of the laser diode 203 and the acceptance angle of the optical fiber 206 may result in significant coupling loss between the two components.

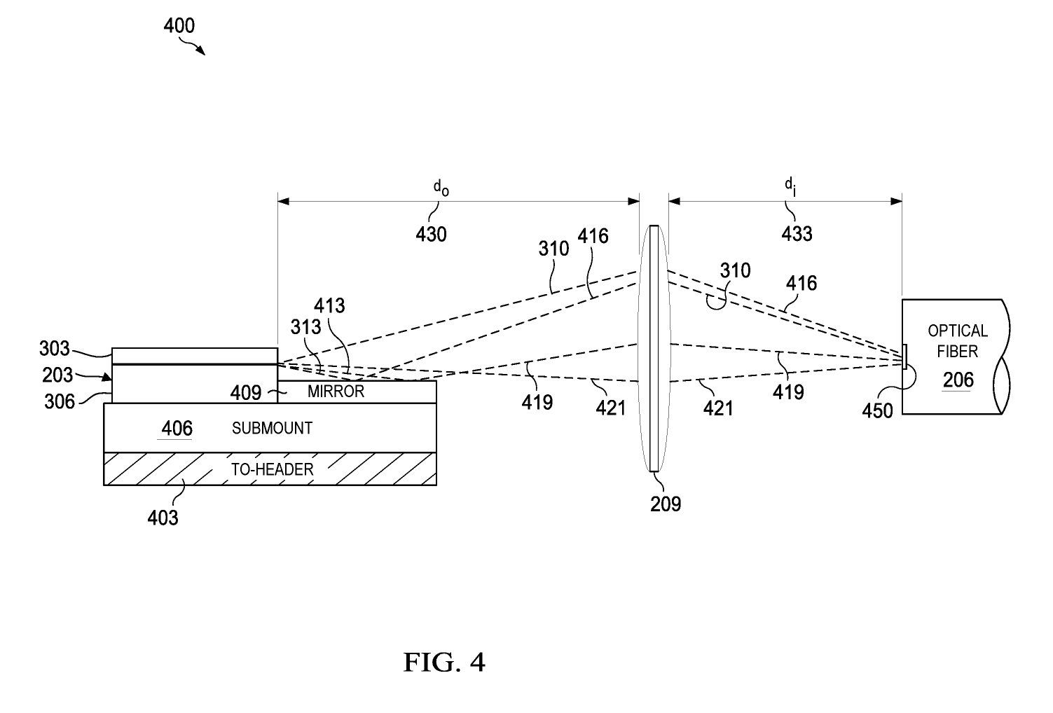

FIG. 4 is a diagram of a TOSA 400 according to an embodiment of the disclosure. The TOSA 400 comprises a laser diode (or DFB laser) 203, a submount 406, a lens 209, and an optical fiber 206. The submount 406 comprises a metal with dielectric properties, such as aluminum nitride (AIN) or other suitable materials. The submount 406 comprises a mirror 409 formed or disposed on the submount 406 and adjacent to or abutting the laser diode 203, and in one embodiment, the end of the laser diode 203 including the output aperture 350. The mirror 409 may be any metal with reflective properties, such as titanium (Ti), gold (Au), and/or another suitable material. In an embodiment, the mirror 409 is a flat mirror that is disposed on top of submount 406. The mirror 409 may be coated on the submount 406 at a low cost. In an embodiment, the mirror 409 is a thin planar element that is substantially parallel to the active layer 306 of the laser diode 203.

In an embodiment, laser diode 203 is flip-chip bonded to the submount 406, where the upper surface 307 is coupled to the submount 406. In this way, laser diode 203 is flipped upside down so that contact points that are typically on the upper surface 307 are now adjacent to the submount 406. In an embodiment, the contact points on the upper surface 307 are solder bumps that are bonded to contact points on the submount 406 and/or the mirror 409. By positioning the active layer 306 of the laser diode 203 adjacent to the submount 406, heat dissipation in TOSA 400 is improved because the heat radiated from the active layer 306 is dissipated into the submount 406. Thus, flip-chip bonding the laser diode 203 to the submount 406 improves the performance of the laser diode 203 when operating in high temperatures.

As shown in FIG. 4, the lens 209 is positioned at a first distance 430 (d₀) from the laser diode 203 and a second distance 433 (dᵢ) from the optical fiber 206. The first distance 430 may be the same or different from the first distance 215 of FIG. 2. The second distance 433 may be the same or different from the second distance 218. The optical fiber 206 comprises an acceptance region or point 450 at about a center, or core, of the optical fiber 206. The acceptance angle 233 may be relative to the acceptance region 450 of the optical fiber 206. In an embodiment, the acceptance region 450 is disposed substantially at a location of the image plane of the lens 209.

As shown in FIG. 4, the laser diode 203 emits an optical signal that diverges into at least four emitted optical signals 310, 313, 413, and 421. The emitted optical signals 310, 313, and 413 are optical signals that diverge elliptically from the output aperture 350 of the laser diode 203 in a vertical direction that is perpendicular to the active layer 306 of the laser diode 203. The mirror 409 on the submount 406 is configured to reflect a portion of the light emitted in a downwardly vertical direction from the laser diode 203. In an embodiment, the mirror 409 is configured to reflect or redirect downward-emitted light into an upward direction to reshape and reduce the vertical far field angle 323 of the laser diode 203. The reflection may reduce the vertical far field angle 323 by about half in some embodiments.

As shown in FIG. 4, the optical signals that diverge downward in a vertical direction are the emitted optical signals 313 and 413. The mirror 409 reflects emitted optical signals 313 and 413 upwards, as reflected optical signals 416 and 419, respectively. There may be some emitted optical signals that do not hit the mirror 409, such as emitted optical signal 421.

Even though the TOSA 400 may only reduce the vertical far field angle 323 of the laser diode 203 in a vertical direction, the TOSA 400 produces an output beam with a more circular shape, thereby substantially matching (or more closely approximating) the circular mode field 318 of the optical fiber 206. For example, the vertical far field angle 323 of the output beam or the light emitted from the laser diode 203 in the embodiment of the TOSA 400 shown in FIG. 4 may be reduced from about 30° to about 16°. The horizontal far field angle 326 may remain at about 20°. The reduction in the vertical far field angle 323 provides a better match between the far field angle of the laser diode 203 and the acceptance angle of the optical fiber 206. It should be noted that a standard DFB laser typically comprises a significantly greater vertical far field angle than a horizontal far field angle.

In the TOSA 400, the lens 209 focuses and directs the emitted optical signals 310 and 421 emitted from the laser diode 203 and the reflected optical signals 416 and 419 to the acceptance region 450 of an optical fiber 206. The phases of the emitted optical signal 310 and the reflected optical signals 416 and 419 comprise substantially the same phase at the image plane of the lens 209, thus no optical interference occurs when the optical signals 310, 416, 419, and 421 reach the acceptance region 450 of the optical fiber 206.

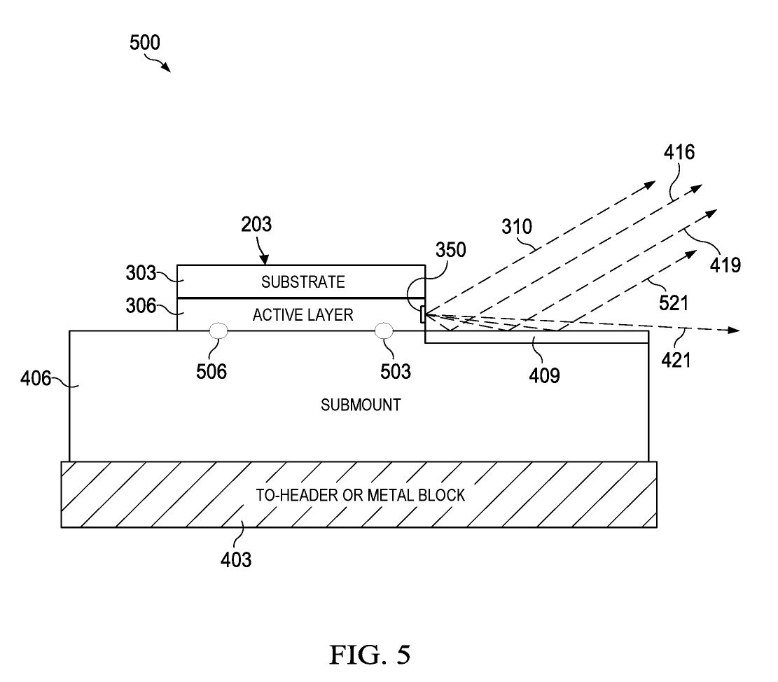

FIG. 5 is a diagram of a portion 500 of the TOSA 400 according to an embodiment of the disclosure. The portion 500 includes the submount 406, the mirror 409, the laser diode 203, emitted optical signals 310 and 421, and reflected optical signals 416, 419, and 521. In an embodiment, the submount 406 is disposed on a TO-header 403 of TOSA 400.

In an embodiment, the mirror 409 may be disposed on the submount 406 such that the mirror 409 extends from an edge of the laser diode 203 at a length sufficient enough to reflect a portion of the optical signals that are downwardly vertically emitted from the laser diode 203. For example, as shown in FIG. 4, the mirror 409 extends from an edge of the laser diode 203 comprising the output aperture 350 to an edge of the submount 406. In another embodiment, the mirror 409 may extend from any point on the surface of the submount 406 under the laser diode 203 to any point past the edge of the laser diode 203 comprising the output aperture 350 so long as a portion of the optical signals emitted from the laser diode 203 are reflected by the mirror 409.

In an embodiment, the mirror 409 may be formed by polishing the surface of the submount 406. In this embodiment, the submount 406 has a reflective enough surface for reflecting the optical signals emitted from the laser diode 203. In another embodiment, a metal layer with reflective properties, such Ti and/or Au, is deposited on the surface of the submount 406 to comprise the mirror 409.

In an embodiment, the laser diode 203 is flip-chip bonded to the submount 406. As shown in FIG. 5, the active layer 306 is coupled to the submount 406 instead of to the substrate 303. In addition, the output aperture 350 of the laser diode 203 is closer to the submount 406 when the laser diode 203 is flip-chip bonded to the submount 406. This proximity between the output aperture 350 and the mirror 409 enables a greater amount of the emitted optical signals to be reflected than if the output aperture 350 is farther away from the mirror 409.

In an embodiment, the laser diode 203 is coupled to the submount 406 and/or the mirror 409 via electrical contacts 506 and 503. Electrical contacts 506 and 503 may be formed by soldering together metal contact points on the laser diode 203 to the metal contact points on the submount 406. As the active layer 306 comprises a waveguide and grating responsible for generating the light, the active layer 306 emits more heat than the substrate 303. Since the active layer 306 is substantially adjacent to the submount 406, the submount 406 is configured to dissipate some of the heat from the active layer 306. In this way, TOSA 400 provides more heat dissipation than a traditional TOSA.

The light emitted from the output aperture 350 of the laser diode 203 includes emitted optical signals 310 and 421 and reflected optical signals 416, 419, and 521. The reflected optical signals 416, 419, and 521 are emitted from the output aperture 350 and reflected from the mirror 409 upwards and to the right. It should be noted that the emitted optical signals 310 and 421 are not reflected from the mirror 409, but may still be captured by the lens 209, which focuses the optical signals 310, 419, 416, 521, and 421 and directs the focused optical signals 310, 419, 416, 521, and 421 toward the optical fiber.

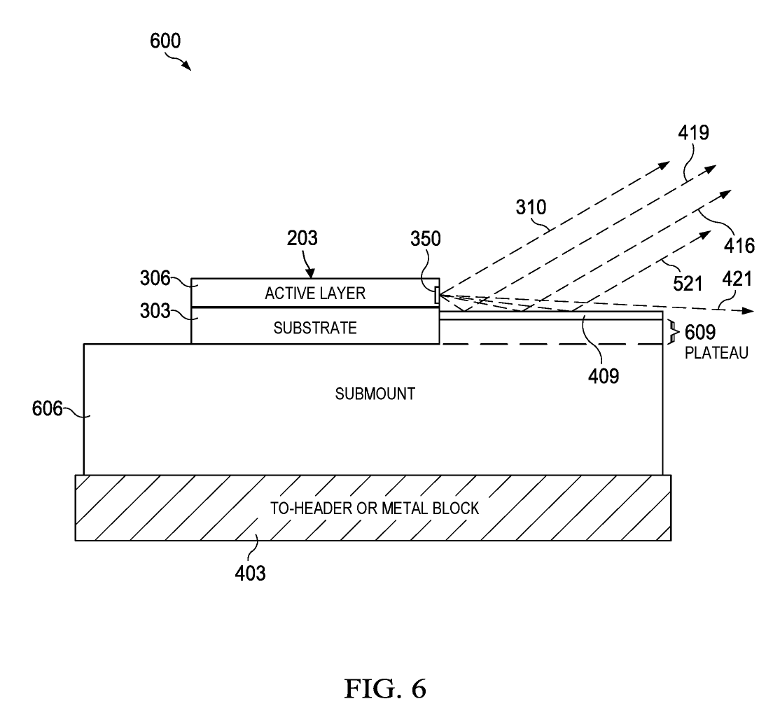

FIG. 6 is a diagram of a portion 600 of the TOSA 400 according to another embodiment of the disclosure. The portion 600 is similar to portion 500, except that the submount 606 in the portion 600 includes a plateau 609 so that the output aperture 350 is closer to the mirror 409, i.e., the laser diode 203 does not need to be flip-chip bonded to the submount 606. The portion 600 of the TOSA 400 includes the submount 606, the mirror 409, the laser diode 203, emitted optical signals 310 and 421, and reflected optical signals 416, 419, and 521.

The submount 606 is similar to the submount 406 in that the submount 606 may be disposed on either the TO-header 403 or a substrate on the TO-header 403. The mirror 409 is disposed on the plateau 609. The plateau 609 is a block comprising the same material as the submount 606, and includes a substantially planar surface that is substantially parallel to the active layer 306 of the laser diode 203. In the embodiment shown in FIG. 6, the plateau 609 extends from an edge of the laser diode 203 comprising the output aperture 350 to an edge of the submount 606. In other embodiments, the plateau 609 may extend from the edge of the laser diode 203 to any point on the surface of the submount 606 so long as at least some of the optical signals are reflected by the mirror 409. A height of the plateau 609 may be based on the distance of the output aperture 350 above the submount 606. The height of the plateau 609 may be minimal, wherein the mirror 409 is located only a small distance above the surface of the submount 606. Alternatively, the plateau 609 may have a height that is a large percentage of the distance to the output aperture 350. When the mirror 409 is disposed relatively near the surface of the plateau 609, the mirror 409 is located relatively far below the output aperture 350. For example, in some embodiments the height of the mirror 409 is about 100 micrometers (μm), or a few μm below the output aperture 350.

As shown in FIG. 6, the substrate 303 is coupled to the surface of the submount 606, and the active layer 306 is farther from the submount 606 than the substrate 303. In this embodiment, the laser diode 203 does not need to be flip-chip bonded to the submount 606. This is because the output aperture 350 from which optical signals are emitted is proximate to the mirror 409 because of the plateau 609. In this embodiment, there is no need to flip the laser diode 203 to be closer to the mirror 409 because the plateau 609 brings the mirror close to the output aperture 350 of the laser diode 203. In the embodiment shown in FIG. 6, the optical signals 310 and 421 are emitted from the output aperture 350 of the laser diode 203, and the reflected optical signals 419, 416, and 521 are reflected from the mirror 409.

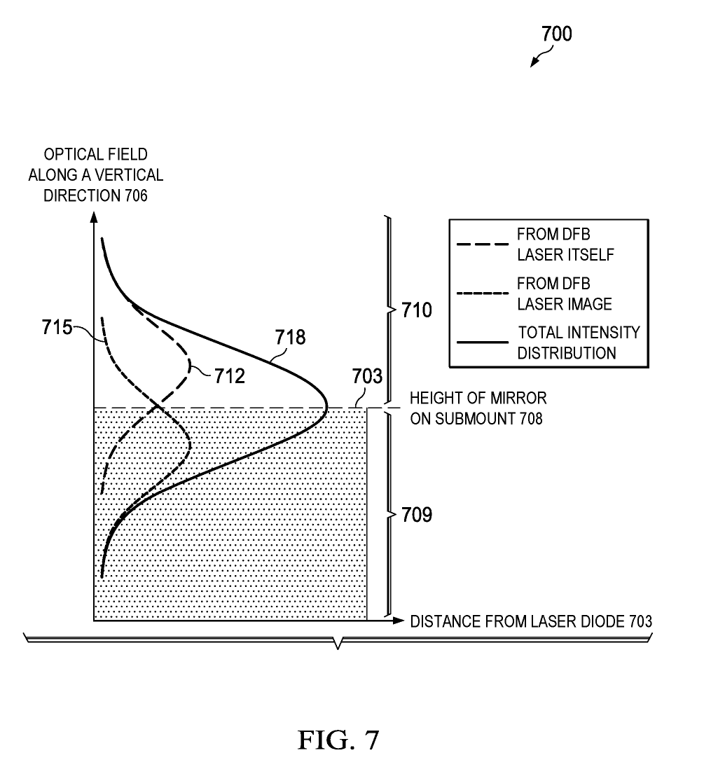

FIG. 7 is a graph 700 illustrating the optical field from the output aperture 350 of the laser diode 203 after being reflected by mirror 409 according to an embodiment of the disclosure. With the mirror 409 placed beneath the output aperture 350 of the laser diode 203, the optical field comprises the emitted optical signals that are emitted by the output aperture 350 and not reflected by the mirror 409 and the reflected optical signals that are emitted by the output aperture 350 and are reflected by the mirror 409. The optical field of the reflected optical signals is substantially the same as the optical field of the emitted optical signals. The emitted optical signals and the reflected optical signals are then passed through the lens 209, which is configured to focus the emitted optical signals and the reflected optical signals onto a focal point at an image plane. The image plane may be substantially located on the acceptance region 450 at the core of the optical fiber 206 in some embodiments. A diameter of a core of a standard single mode optical fiber is about 8-10 μm, and a cladding diameter of the standard single mode optical fiber is 125 μm. A mode field diameter of the core of the optical fiber 206 is about 9 μm. In some embodiments, the emitted optical signals and the reflected optical signals are close together within 9 μm after the lens 209 focuses the emitted optical signals and the reflected optical signals. Therefore, the closer together the emitted optical signals and the reflected optical signals are after being focused by the lens 209, the less coupling loss experienced between the laser diode 203 and the optical fiber 206.

Graph 700 illustrates the optical field along the vertical direction (y-axis 706) relative to the distance from the laser diode 203 (x-axis 703). Horizontal line 708 represents the height of the mirror 409. Portion 709 represents the optical field of the emitted optical signals and the reflected optical signals below the mirror 409, and portion 710 represents the optical field of the emitted optical signals and the reflected optical signals that are above the mirror 409. Curve 712 represents the optical field of the emitted optical signals, and curve 715 represents the optical field of the reflected optical signals that are reflected off mirror 409. Curve 718 represents the total optical power of the combined optical fields represented by curve 712 and curve 715. Note that the optical field vanishes beneath the mirror, so only the portions of the curves above the mirror represent the optical field.

In an embodiment, the optical signal 220 emitted from the laser diode 203 may be approximated by an elliptical Gaussian beam. The propagation and diffraction of the optical signal 220 may be analyzed by considering two-dimensional propagations in vertical direction (denoted as x) and the direction toward the optical fiber 206 (denoted as z) without including the horizontal direction since the mirror 409 does not modify the beam propagation in the horizontal direction. The laser diode 203 is positioned at a distance, denoted as h, above the mirror 409, which is slightly above an optical axis of the optical fiber 206. The electrical field of a two-dimensional Gaussian beam from emitted optical signal 220 is as follows:

$$E ( x , z ) = \frac{{w}_{0}}{w ( z )} exp [ - \frac{{( x - h )}^{2}}{{w}^{2} ( z )} ] exp [ - j \frac{{k ( x - h )}^{2}}{2 R ( z )} ] exp \{ - j [ kz - φ ( z ) ] \} for x > 0 \\ where \\ w ( z ) = {w}_{0} \sqrt{1 + {( z / {z}_{R} )}^{2}} represents the spot size , \\ R ( z ) = z [ 1 + {( {z}_{R} / z )}^{2} ] represents the radius of curvature , \\ φ ( z ) = {tan}^{- 1} ( z / {z}_{R} ) represents the Guoy phase shift , \\ {z}_{R} = \frac{π {w}_{0}^{2}}{λ} \qquad ( 1 )$$

where k is the wave number of the laser diode 203, or DFB laser, output, and w₀ is the waist size of the beam.

The mirror 409 on the submount 406 and 606 essentially folds the electrical field for x<0, and the electrical field of the reflected optical signals 416 and 419 may be expressed as:

$${E}_{r} ( x , z ) = \frac{{w}_{0}}{w ( z )} exp [ - \frac{{( x + h )}^{2}}{{w}^{2} ( z )} ] exp [ - j \frac{{k ( x + h )}^{2}}{2 R ( z )} ] exp \{ - j [ kz - φ ( z ) ] \} for x > 0 \qquad ( 2 )$$

For simplicity, the lens 209 may be assumed as a thin lens, the ABCD matrix of the lens 209 is as follows:

$$( \begin{matrix}A & B \\ C & D\end{matrix} ) = ( \begin{matrix}1 & 0 \\ - \frac{1}{f} & 1\end{matrix} ) \qquad ( 3 )$$

The transformation of a Gaussian beam by a thin lens 209 is as follows:

$${q}_{2} = \frac{{Aq}_{1} + B}{{Cq}_{1} + D} \\ where \\ {q}_{1} = \frac{1}{{R}_{1}} - j \frac{λ}{π {w}_{1}^{2}} \\ {q}_{2} = \frac{1}{{R}_{2}} - j \frac{λ}{π {w}_{2}^{2}} \qquad ( 4 )$$

where j represents the imaginary component, w₁ and w₂ are the spot sizes of the Gaussian beam before and after the thin lens 209, respectively, and f is the focal length of the thin lens 209. Therefore,

$${q}_{2} = \frac{1}{{R}_{2}} - j \frac{λ}{π {w}_{2}^{2}} = \frac{\frac{f}{{R}_{1}} - j \frac{λ f}{π {w}_{1}^{2}}}{f - \frac{1}{{R}_{1}} + j \frac{λ}{π {w}_{1}^{2}}} \qquad ( 5 )$$

For the thin lens 209, w₁ is about the same as w₂. Equating the real and imaginary components of both sides of equation (5) results in the following:

$$\frac{1}{{R}_{2}} ( f - \frac{1}{{R}_{1}} ) + \frac{{λ}^{2}}{π {w}_{1}^{4}} = \frac{f}{{R}_{1}} ⇒ {R}_{2} = \frac{{fR}_{1} - 1}{f - {λ}^{2} {R}_{1} / π {w}_{1}^{4}} \qquad ( 6 )$$

For the incident beam, both E(x, z) and Eᵣ(x, z), the distance of the object, for example, the laser diode 203 front facet, to the lens 209 is distance 430 (dₒ). Then the radius of curvature at the z=dₒ is as follows:

$${R}_{1} = R ( {d}_{o} ) = {d}_{o} [ 1 + {( {z}_{R} / {d}_{o} )}^{2} ] = {d}_{o} + \frac{{z}_{R}^{2}}{{d}_{o}} \approx {d}_{o} for {z}_{R} << {d}_{o} \qquad ( 7 )$$

The spot-size is as follows:

w₁=w(dₒ)=w₀\sqrt{1+(dₒ/z_{R})²}≈w₀dₒ/z_{R} for z_{R}<<dₒ (8)

Therefore, the curvature of the Gaussian beam after passing the lens 209 is as follows:

$${R}_{2} = \frac{{fR}_{1} - 1}{f - {λ}^{2} {R}_{1} / π {w}_{1}^{4}} \approx \frac{{fd}_{o} - 1}{f - {λ}^{2} {z}_{R} / π {w}_{0}} \qquad ( 9 )$$

For R_{2 <0}, the lens 209 can focus the diverged Gaussian beam to a narrower beam waist. The phase of the light at the lens 209 for both E(x, z) and Eᵣ(x, z) fields are as follows:

$${ϕ}_{E} ( x , {d}_{o} ) = - \frac{{k ( x - h )}^{2}}{2 R ( z )} - {kd}_{o} - φ ( {d}_{o} ) \\ {ϕ}_{Er} ( x , {d}_{o} ) = - \frac{{k ( x + h )}^{2}}{2 R ( z )} - {kd}_{o} - φ ( {d}_{o} ) \qquad ( 10 )$$

Therefore, on the z=dₒ plane, the phase of φ_{Er}(x, dₒ) is different from E(x, z). In some embodiments, there may be an interference pattern at the lens 209. Even though the radius of curvature for E(x, z) and Eᵣ(x, z) fields is the same before or after the lens 209, the small displacement between these two fields creates the interference pattern.

For Gaussian beam propagation in free space, the ABCD matrix is as follows:

$$( \begin{matrix}A & B \\ C & D\end{matrix} ) = ( \begin{matrix}1 & {d}_{i} \\ 0 & 1\end{matrix} ) \qquad ( 11 )$$

where dᵢ, is the propagation distance. Then, after a distance of dᵢ, the Gaussian beam is transformed to a beam with radius of curvature

$${R}_{3} ( {d}_{i} ) = \frac{1}{1 / {R}_{2} + {d}_{i}} = \frac{{R}_{2}}{1 + {d}_{i} {R}_{2}} \qquad ( 12 )$$

when 1+dᵢR₂ =0, where distance 433 (dᵢ) may be expressed as

$${d}_{i} = - \frac{1}{{R}_{2}} ,$$

the radius of curvature is infinity. This happens at

$${d}_{i} = - \frac{1}{{R}_{2}} ,$$

where R₂<0 for both E(x, z) and Eᵣ(x, z) fields. When the radius of curvature is infinite, the phase is constant on the z=dᵢ plane, as both fields go through the same transformation. The field at dᵢ=−1/R₂ plane as follows:

$$E ( x , {d}_{i} ) = exp [ - \frac{{( x - {h}_{i} )}^{2}}{{w}_{3}^{2} ( {d}_{i} )} ] \{ - j [ k ( {d}_{o} + {d}_{i} ) - {tan}^{- 1} ( ( {d}_{o} + {d}_{i} ) / {z}_{R} ) ] \} for x > 0 \\ {E}_{r} ( x , {d}_{i} ) = exp [ - \frac{{( x + {h}_{i} )}^{2}}{{w}_{3}^{2} ( {d}_{i} )} ] \{ - j [ k ( {d}_{o} + {d}_{i} ) - {tan}^{- 1} ( ( {d}_{o} + {d}_{i} ) / {z}_{R} ) ] \} for x > 0 \qquad ( 13 )$$

where w₃²(dᵢ)=w₀²(1−dᵢ/f)²+w₀²(dᵢ/zᵣ)²

However, the centers of the transformed Gaussian fields Eᵣ (x,d₀) and E(x, z) have a small displacement, hᵢ=hdᵢ/dₒ. This displacement is required to be smaller than the diameter of the optical fiber 206. Thus, the distance between the mirror 409 and the laser diode 203 front facet may be small, which is achieved by flip-chip bonding the laser diode 203 to the submount 406. In addition, the half Gaussian beam for the field E(x, z) is tilted slightly downward by an angle of θ=−h/dₒ, while the half Gaussian beam for the field Eᵣ(x, z) is tilted slightly upward by an angle of θ=−h/dₒ. If h is significantly less than dₒ, where h is about 1 μm to about 2 μm and dₒ>1 millimeter (mm), this tilt may be neglected.

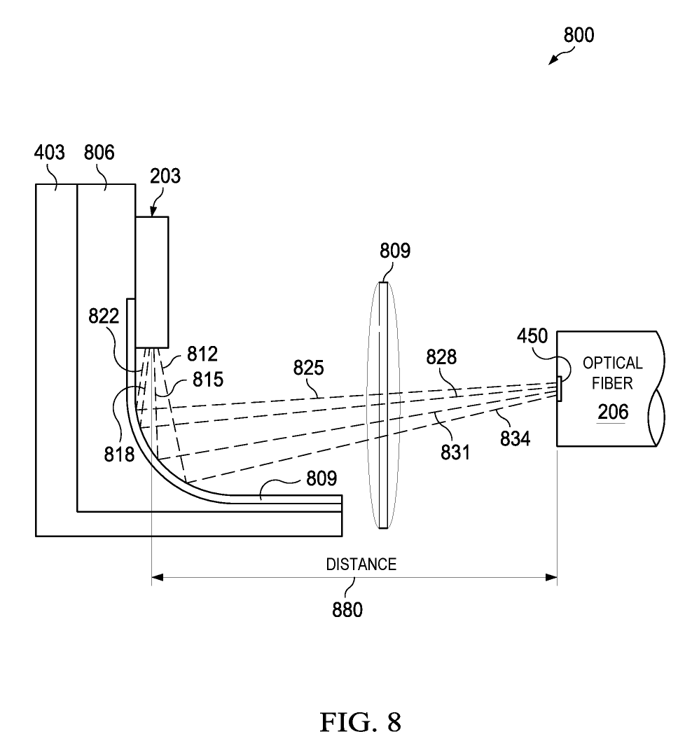

FIG. 8 is a diagram of a TOSA 800 according to another embodiment of the disclosure. The TOSA 800 comprises a laser diode 203, a submount 806, and an optical fiber 206. The TOSA 800 is similar to the TOSA 400, except that the TOSA 800 comprises a submount 806 with a curved or substantially doubly concave surface, and a mirror 809 disposed on the submount 806. Mirror 809 is also concave instead of flat, being curved in both a longitudinal direction with regard to the top surface of the submount 806 and in a transverse direction. The output aperture 350 of the laser diode 203 faces the substantially doubly concave surface of the mirror 809. Unlike mirror 409 in FIGS. 4-5 that is only configured to reshape the vertical far field angle 323 of the laser diode 203, the mirror 809 is configured to reshape both the vertical far field angle 323 and the horizontal far field angle 326.

The laser diode 203 may or may not be flip-chip bonded to the submount 806. The surface proximate to the substrate of the laser diode 203 is coupled to submount 806. The submount 806 is similar to the submount 406 in that submount 806 also comprises a dielectric, such as AIN or another suitable material. Submount 806 may also be disposed on either the TO-header 403 or a substrate. However, unlike submount 406, submount 806 is substantially L-shaped.

The mirror 809 is a curved or substantially doubly concave mirror that is disposed on at least the interior surface of the submount 806. The mirror 809 is a semi-spherical or toroidal mirror that has a reflective surface, which curves downward to create a curved trough-like shape, curving substantially ninety degrees away from the laser diode 203 in the embodiment shown. Alternatively, other amounts of curvature can be employed. For example, the mirror 809 is a semi-tubularly concave surface including a curving, which is a substantially 90° bend. In an embodiment, the curving is around a vertex of the mirror 809. In an embodiment, a vertex of the mirror 809 is disposed at a distance 880 from the acceptance region 450 of the optical fiber 206. The vertex of the mirror 809 may be the center point of the mirror 809 in some embodiments. The distance 880 is based on the optical field of the light emitted from the laser diode 203 and an angle of incidence of light with respect to the mirror 809.

As shown in FIG. 8, the laser diode 203 emits light that diverges into at least four emitted optical signals 812, 815, 818, and 822. The emitted optical signals 812, 815, 818, and 822 are optical signals that diverge elliptically from the output aperture 350 of the laser diode 203 in a horizontal direction and/or a vertical direction. The horizontal direction is parallel to the active layer 306 of the laser diode 203, and the vertical direction is substantially perpendicular to the active layer 306 of the laser diode 203. The mirror 809 on the submount 806 is configured to reflect and re-direct substantially all of the light emitted from the laser diode 203.

In an embodiment, the substantially doubly concave shape of the mirror 809 receives the emitted optical signals 812, 815, 818, and 822, and redirects the reflected optical signals 825, 828, 831, and 834 at a substantially 90° angle toward a focal point located at an image plane. The focal point is a point in space at an image plane at which optical signals incident toward the mirror and reflected off the mirror 809 will meet after reflection. In an embodiment, TOSA 800 can be structured so that the focal point of the mirror 809 is substantially on or around the acceptance region 450 on the optical fiber 206. This way, the reflected optical signals 825, 828, 831, and 834 automatically converge toward the core of the optical fiber, thereby reducing the far field angle 230 of the laser diode 203. In this embodiment, there may be little to no coupling loss between the laser diode 203 and the optical fiber 206.

In some embodiments, a lens 209 may be positioned in between the submount 806 and the optical fiber 206. However, since the lens 209 is typically used to focus reflected optical signals, such a lens 209 is not needed in this embodiment. This is because the reflected optical signals 825, 828, 831, and 834 are substantially focused to a focal point due to the substantially doubly concave shape of mirror 809. Therefore, the TOSA 800 eliminates the need for a lens 209 in an ONU 120 or OLT 110. Instead, a less costly glass window can be disposed in place of the lens 209.

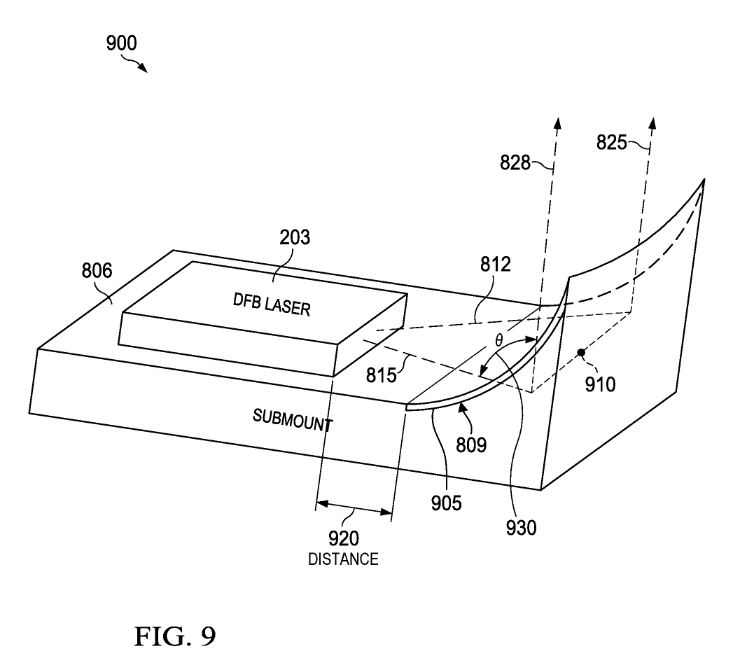

FIG. 9 is a diagram of a portion 900 of the TOSA 800 according to an embodiment of the disclosure. The figure shows the substantially doubly concave shape of the mirror 809. The portion 900 includes the submount 806, the mirror 809, the laser diode 203, emitted optical signals 812 and 815, and reflected optical signals 828 and 825. In an embodiment, the submount 806 is disposed on a TO-header of TOSA 800. In another embodiment, the submount 806 is disposed on a substrate, such as a metal block, which is disposed on the TO-header.

As shown in FIG. 9, the laser diode 203 is disposed on the submount 806 at a distance 920 away from the mirror 809. The distance 920 is based on the optical field of the light emitted from the laser diode 203 and an angle of incidence of the emitted light with respect to the mirror 809. The submount 806 is formed in a substantially L-shape and comprises a substantially doubly concave interior surface 905 upon which the mirror 809 is disposed. In various embodiments, the interior surface 905 may be any shape so long as the interior surface 905 supports the structure of the mirror 809. The interior surface 905 of the submount 806 may be concave, or curved, so as to support the mirror 809 since mirror 809 is also concave. For example, the interior surface 905 of the submount 806 is a semi-tubularly concave surface including a bend or curving region, which is a substantially regular and continuous 90° bend around a center point of the interior surface 905 in the embodiment shown. In an embodiment, the interior surface 905 may have the same shape as the mirror 809.

In an embodiment, the mirror 809 can extend along the submount 806 so long as the mirror 809 reflects the light emitted from the laser diode 203. The mirror 809 comprises a vertex 910. The vertex 910 is the geometric center of the concave structure of the mirror 809, and the mirror 809 curves radially around the vertex 910. The mirror 809 is a semi-spherical or toroidal mirror that has a reflective surface, which bulges inward (away from the light emitted from the laser diode 203). For example, the mirror 809 is also a semi-tubularly concave surface including a curving region, which is a substantially 90° bend around the vertex 910 of the mirror 809 in the embodiment shown.

The light emitted from the output aperture 350 of the laser diode 203 includes emitted optical signals 812 and 815 and reflected optical signals 825 and 828. The emitted optical signals 812 and 815 may be optical signals in a horizontal direction or a vertical direction that are emitted from the output aperture 350. The emitted optical signals 812 and 815 impinge on a surface of the mirror 809. The emitted optical signals 812 and 815 are reflected from the surface of the mirror 809 based on a reflection angle 930 of the mirror 809. The reflection angle 930 is the angle by which emitted optical signals 812 and 815 are reflected to produce the reflected optical signals 825 and 828. In an embodiment, the emitted optical signals 812 and 815 are reflected by the mirror 809 at a reflection angle 930 of substantially 90° to form the reflected optical signals 825 and 828. The reflected optical signals 825 and 828 may be optical signals in a horizontal direction or a vertical direction that are reflected by the mirror 809. The concave shape of the mirror 809 focuses the reflected optical signals 825 and 828 to a focal point. In an embodiment, the concave shape of the mirror 809 reshapes and reduces the far field angle 230 of the laser diode 203. Therefore, the portion 900 can be structured such that the image of reflected optical signals 825 and 828 is set to be the acceptance region 450 at a core of the optical fiber 206.

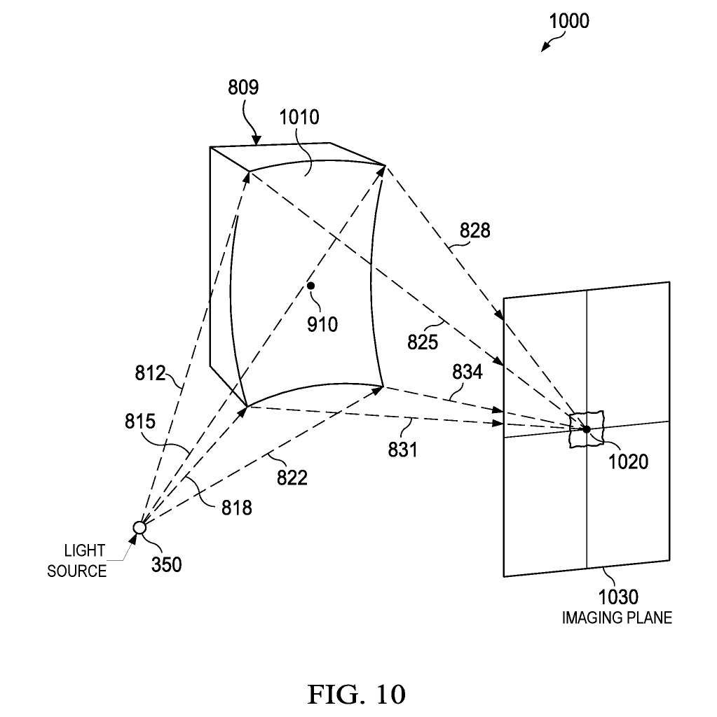

FIG. 10 is a diagram 1000 of a mirror 809 according to various embodiments of the disclosure. Mirror 809 is a concave shape and comprises a concave surface 1010. For example, the mirror 809 shown in FIG. 10 is a toroidal mirror. A toroidal mirror is an aspherical mirror or a form of a parabolic reflector which has a different focal distance 920 depending on a deflection angle 930 of the mirror. In various embodiments, the mirror 809 may be spherical, as well as elliptic, parabolic, or hyperbolic, depending on the location of the acceptance region 450 of the optical fiber 206 and the location of the output aperture 350 of the laser diode 203. The base of the mirror 809 has a rectangular shape. However, it should be appreciated that the base of the mirror 809 may be any shape so long as the mirror 809 may be formed on the interior surface 905 of the submount 806.

The concave surface 1010 comprises a vertex 910. The vertex 910 is a point or an area at the center of the concave surface 1010. In an embodiment, the mirror 809 or the concave surface 1010 curves around the vertex 910. The deflection angle 930 of the mirror 809 is about 90°. However, as should be appreciated, the deflection angle 930 of the mirror 809 can be any angle such that laser diode 203 emits optical signals that are reflected off of the concave surface 1010 onto a focus point, which is at an acceptance point of the optical fiber 206. In an embodiment, the deflection angle 930 can be based on the focal distance 920, the distance 880 from the mirror 809 to the acceptance region 450 of the optical, and/or the optical field of the optical signals emitted from the laser diode 203.

As shown in FIG. 10, output aperture 350 of the laser diode 203 emits the emitted optical signals 812, 815, 818, and 822, which impinge upon the concave surface 1010 of mirror 809. As shown in FIG. 10, the emitted optical signals 812, 815, 818, and 822 impinge at different points on the concave surface 1010 of the mirror 809. The concave surface 1010 of the mirror 809 reflects the emitted optical signals 812, 815, 818, and 822 from the different points on the concave surface 1010 as reflected optical signals 825, 828, 831, and 834, respectively. The reflected optical signals 825, 828, 831, and 834 are reflected from the different points on the concave surface 1010 to a focus point 1020 on an image plane 1030. The concave shape of the mirror 809 enables the reflected optical signals 825, 828, 831, and 834 to be focused and substantially collimated at the distance 880 from the mirror 809. The image plane 1030 is a plane in which the reflected optical signals 825, 828, 831, and 834 are substantially collimated. The focal point 1020 is a point or area on the image plane 1030 at which reflected optical signals 825, 828, 831, and 834 are substantially collimated. In an embodiment, an acceptance region 450 of an optical fiber 203 can be positioned substantially at the focal point 1020 of the reflected optical signals 825, 828, 831, and 834. In this way, the optical signals emitted from the laser diode 203 are accepted by the optical fiber 206 without experiencing coupling loss due to diffraction of the optical signals emitted by the laser diode 203.

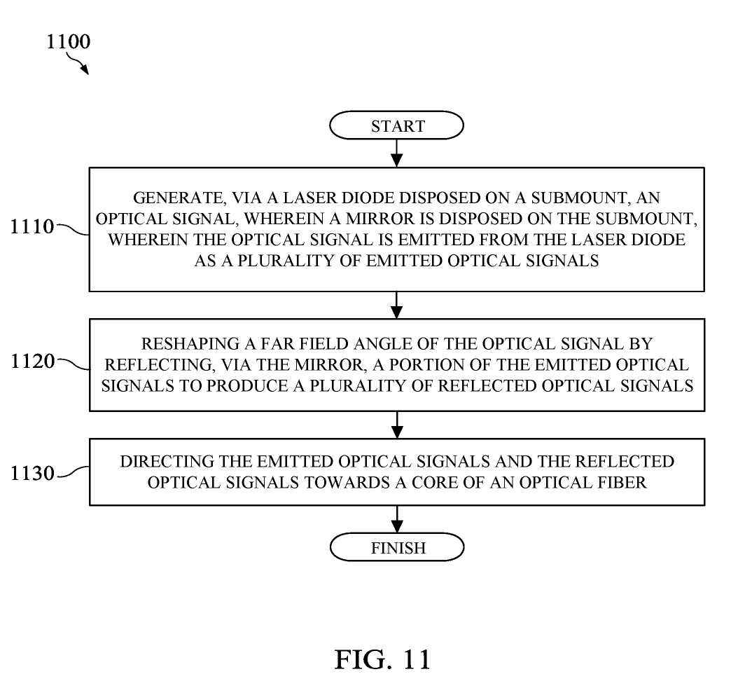

FIG. 11 is a flowchart of a method 1100 for reducing a far field angle of a laser diode according to an embodiment of the disclosure. The method 1100 is implemented by an optical transceiver comprising TOSAs 400 or 800 or portions 500, 600, or 900 when performing laser-to-fiber coupling. At step 1100, an optical signal is generated. For example, laser diode 203 generates the optical signal 220. The laser diode 203 emits the optical signal 220 as one or more emitted optical signals 310, 313, 316, 320, 413, 421, 812, 815, 818, and 822. In an embodiment, the laser diode 203 may be coupled to submount 406, 606, or 806. In an embodiment, a mirror may be disposed on the submount. The mirror may be mirror 409 or 809. At step 1120, reshaping a far field angle of the optical signal by reflecting, via the mirrored submount, a portion of the optical signal to produce a reflected optical signal. For example, a far field angle 230 of the emitted optical signal is reshaped by reflecting, via either mirror 409 or mirror 809, a portion of the emitted optical signal to produce a reflected optical signal. The reflected optical signal is similar to reflected optical signal 416, 419, 521, 825, 828, 831, or 834.

In an embodiment where the mirror is the flat mirror 409, a lens 209 may be used to further direct the emitted optical signals and the reflected optical signals to the optical fiber 206, and the vertical far field angle 323 is reduced. In an embodiment where the mirror is a substantially doubly concave mirror 809, a lens is not required, and both the vertical far field angle 323 and the horizontal far field angle 326 are reduced. At step 1130, the reflected optical signals are directed towards a core of an optical fiber. For example, the reflected optical signals are directed to an acceptance region 450 of the optical fiber 206. For example, the acceptance region 450 may be located at a core of the optical fiber 206. In an embodiment, the optical transceiver is structured such that at the focus point, the reflected optical signals are substantially collimated together at the acceptance region 450 of the optical fiber 206.

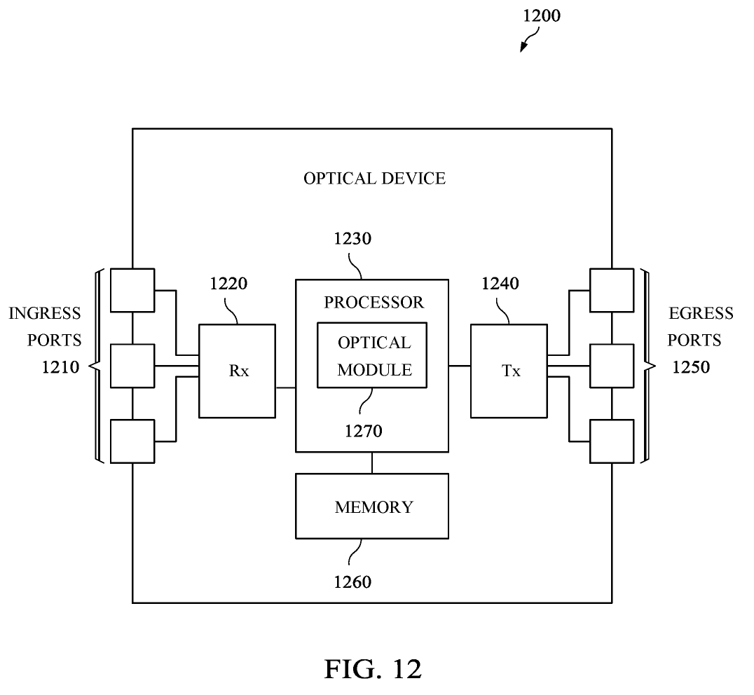

FIG. 12 is a diagram of an optical device 1200 according to an embodiment of the disclosure. The optical device 1200 is suitable for implementing the disclosed embodiments described above, such as an ONU 120 or an OLT 110 that includes TOSAs 400 or 800 or portions 500, 600, or 900. The optical device 1200 comprises ingress ports 1210; a receiver unit (Rx) 1220 coupled to the ingress ports 1210 and configured for receiving data; a processor, logic unit, or central processing unit (CPU) 1230 coupled to the Rx 1220 and configured for processing the data; a transmitter unit (Tx) 1240 coupled to the processor 1230; and egress ports 1250 coupled to the Tx 1240 and configured for transmitting the data; and a memory 1260 coupled to the processor 1230 and configured for storing the data. In an embodiment, the optical device 1200 is an ONU 120 or an OLT 110. In such an embodiment, Tx 1240 and/or the Rx 1220 are optical transceivers included in an ONU 120 or an OLT 110. The Tx 1240 and/or the Rx 1220 may include the one of the TOSAs 400 or 800 or portions 500, 600, or 900. The optical device 1200 may also comprise optical-to-electrical (OE) components and/or electrical-to-optical (EO) components coupled to the ingress ports 1210, the Rx 1220, the Tx 1240, and the egress ports 1250 for egress or ingress of optical or electrical signals.

The processor 1230 is implemented by any suitable combination of hardware, middleware, firmware, and software. The processor 1230 may be implemented as one or more CPU chips, cores (e.g., as a multi-core processor), field-programmable gate arrays (FPGAs), application specific integrated circuits (ASICs), or digital signal processors (DSPs). The processor 1230 is in communication with the ingress ports 1210, Rx 1220, Tx 1240, egress ports 1250, and memory 1260. In an embodiment, the processor 1230 comprises an optical module 1270. In an embodiment, the optical module 1270 may be configured to control the laser diode 203.

The memory 1260 comprises one or more disks, tape drives, or solid-state drives and may be used as an over-flow data storage device, to store programs when such programs are selected for execution, and/or to store instructions and data that are read during program execution. The memory 1260 may be volatile and/or non-volatile and may be read-only memory (ROM), random-access memory (RAM), ternary content-addressable memory (TCAM), or static random-access memory (SRAM).

In an embodiment, the disclosure includes a means for emitting an optical signal, wherein the optical signal diffracts into a plurality of emitted optical signals, and a means for at least partially reflecting and redirecting the emitted optical signals to produce a plurality of reflected optical signals, and wherein the mirror is further configured to reshape a far field angle of the optical signal.

In an embodiment, the disclosure includes a means for emitting an optical signal, wherein the optical signal diffracts into a plurality of emitted optical signals, at least partially reflecting and redirecting the plurality of emitted optical signals to produce a plurality of reflected optical signals, and wherein the mirror is further configured to reshape a far field angle of the optical signal, and receiving the plurality of emitted optical signals and the plurality of reflected optical signals.

In an embodiment, the disclosure includes a means for generating an optical signal, wherein a mirror is disposed on the submount, wherein the optical signal is emitted from the laser diode as a plurality of emitted optical signals, a means for reshaping a far field angle of the optical signal by reflecting a portion of the plurality of emitted optical signals to produce a plurality of reflected optical signals, and directing the plurality of emitted optical signals and the plurality of reflected optical signals towards a core of an optical fiber.

While several embodiments have been provided in the present disclosure, it may be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and may be made without departing from the spirit and scope disclosed herein.

What is claimed is:

1. An optical device comprising:
a laser diode configured to emit an optical signal, wherein the optical signal diffracts into a plurality of emitted optical signals; and
a submount comprising a mirror, wherein the mirror is configured to at least partially reflect and redirect the plurality of emitted optical signals to produce a plurality of reflected optical signals, and wherein the mirror is further configured to substantially reshape a vertical far field angle of the optical signal.

2. The optical device of claim 1, wherein the plurality of reflected optical signals are substantially collimated and focused before being received at an optical fiber.

3. The optical device of claim 1, wherein the mirror is a flat mirror, wherein a plane of the flat mirror is substantially parallel with an active layer of the laser diode.

4. The optical device of claim 3, wherein the laser diode is flip-chip bonded to the submount.

5. The optical device of claim 1, further comprising a lens positioned between the laser diode and the optical fiber, wherein the lens is configured to focus the plurality of emitted optical signals and the plurality of reflected optical signals together.

6. The optical device of claim 1, wherein the mirror is a substantially doubly concave mirror with a substantially toroidal shape.

7. The optical device of claim 1, wherein the mirror is a substantially doubly concave mirror with a substantially toroidal shape, wherein the mirror is configured to reflect light by about 90 degrees.

8. The optical device of claim 1, wherein the mirror is configured to focus the plurality of reflected optical signals toward an acceptance region of an optical fiber, and wherein the acceptance point on the optical fiber is located substantially at an image plane of the mirror.

9. An optical device comprising:
a laser diode configured to emit an optical signal, wherein the optical signal diffracts into a plurality of emitted optical signals; and
a submount comprising a mirror, wherein the mirror is configured to at least partially reflect and redirect the plurality of emitted optical signals to produce a plurality of reflected optical signals, and wherein the mirror is further configured to substantially reshape a vertical far field angle and a horizontal far field angle of the optical signal.

10. The optical device of claim 9, wherein the plurality of emitted optical signals and the plurality of reflected optical signals are substantially collimated and focused before being received by the optical fiber.

11. The optical device of claim 9, wherein the laser is flip-chip bonded to the submount.

12. The optical device of claim 9, further comprising a lens positioned between the laser diode and the optical fiber, wherein the lens is configured to focus the plurality of emitted optical signals and the plurality of reflected optical signals together.

13. The optical device of claim 9, wherein the mirror is a substantially doubly concave mirror with a substantially toroidal shape, and wherein the mirror is configured to focus the plurality of reflected optical signals toward an acceptance point of an optical fiber.

14. The optical device of claim 13, wherein the mirror is a substantially doubly concave mirror with a substantially toroidal shape, and wherein the mirror is configured to reflect light by about 90 degrees.

15. A method comprising:
generating, via a laser diode disposed on a submount, an optical signal, wherein a mirror is disposed on the submount, wherein the optical signal is emitted from the laser diode as a plurality of emitted optical signals;
reshaping a far field angle of the optical signal by reflecting, via the mirror, a portion of the plurality of emitted optical signals to produce a plurality of reflected optical signals; and
directing the plurality of emitted optical signals and the plurality of reflected optical signals towards a core of an optical fiber.

16. The method of claim 15, wherein reshaping the far field angle comprises reducing a vertical far field angle relative to the laser diode.

17. The method of claim 15, wherein the mirror is a flat mirror, wherein a plane of the flat mirror is substantially parallel with an active layer of the laser diode.

18. The method of claim 15, wherein the mirror is a substantially doubly concave mirror with a substantially toroidal shape, and wherein an image plane of the mirror is substantially located on the core of the optical fiber.

19. The method of claim 15, wherein the mirror is a substantially doubly concave mirror with a substantially toroidal shape and wherein the mirror is configured to reflect light by about 90 degrees.

20. The method of claim 15, further comprising transmitting, via an output aperture of the laser diode, the optical signal to an optical fiber, wherein a portion of the plurality of emitted optical signals are reflected from the mirror to the optical fiber.
